(19) United States
(12) Patent Application Publication
(10) Pub. No.: US 2018/0248108 A1
(43) Pub. Date: Aug. 30, 2018

(54) LAYER AND METHOD FOR THE PRODUCTION THEREOF

(71) Applicant: CeramTec GmbH, Plochingen (DE)

(72) Inventors: Hans-Jürgen SCHREINER, Hersbruck (DE); Tanja EINHELLINGER-MÜLLER, Nürnberg (DE); Tobias SCHMIDT, Lauf (DE); Ralf MOOS, Bayreuth (DE); Michael SCHUBERT, Bayreuth (DE)

(21) Appl. No.: 15/755,195

(22) PCT Filed: Aug. 26, 2016
(86) PCT No.: PCT/EP2016/070162

§ 371 Date: Feb. 26, 2018

(30) Foreign Application Priority Data
Aug. 26, 2015 (DE) 10 2015 216 312.1
Nov. 4, 2015 (DE) 10 2015 221 576.8
Jan. 5, 2016 (DE) 10 2016 200 038.1

(51) Int. Cl. H01L 41/319; H01L 41/08; H01L 41/187; C01G 25/00; C23C 24/04; C23C 28/00

(52) U.S. Cl. CPC H01L 41/319; H01L 41/0815; H01L 41/1876; C01P 2006/40; C23C 24/04; C23C 28/32; C23C 28/345; C01G 25/006

(57) ABSTRACT

The invention relates to a layer having piezoelectric properties and a method for producing a layer having piezoelectric properties, in particular by means of aerosol deposition method (ADM).

The present invention relates to a layer having piezoelectric properties and to a method for producing a layer having piezoelectric properties, in particular by way of an aerosol deposition method (ADM). So far only methods that include a temperature treatment (sintering/annealing) at temperatures >500° C. are known for the production of layers having piezoelectric properties. The state of the art of the method is shown in FIG. 1. FIG. 2 shows how the particles are fragmented into smaller sub-particles when impinging on the substrate. Previously, however, it was necessary to carry out an annealing step >500° C. after this fragmentation into sub-particles so as to generate a piezoelectric effect or a piezoelectric property of the layer.

It was therefore the object of the present invention to provide a layer having piezoelectric properties and a method for producing layers having piezoelectric properties which does not have the aforementioned problems, and in particular dispense with the annealing step >500° C.

If it is possible to apply the layer and/or to anneal at temperatures <500° C., preferably <350° C., and particularly preferably <300° C., there are considerably more application possibilities and considerably more substrates that can be used.

The object is achieved by the provision of a layer having piezoelectric properties, wherein no temperature treatment >500° C. takes place during and after coating. Preferably, the piezoelectric properties of the layer are formed at room temperature or by annealing at temperatures up to a maximum of 350° C. It is particularly preferred that the powder (for the layer) and/or the substrate or the carrier are not heated by means of an external heat source to temperatures above 350° C. during coating. Subsequent temperature treatments at temperatures <300° C. are particularly preferred.

Preferably, the coating is applied to a suitable substrate or a suitable carrier by way of an aerosol deposition method of the powdered raw materials using a gas stream (carrier gases may be air, noble gases, oxygen, nitrogen, hydrogen or mixtures thereof, air being particularly preferred). The substrate or the carrier to which the layer is applied is preferably made of ceramic, plastic, glass, metal, semiconductor or a composite of the aforementioned materials.

The substrate or the carrier preferably has a lower hardness than the bulk material of the powdered raw materials used for the aerosol deposition. The layer can preferably be applied independently of the shape or configuration of the substrate or of the carrier. The substrate or the carrier can have any arbitrary shape, such as curvatures.

The layer having piezoelectric properties of the present invention is preferably a ceramic layer, and particularly preferably the layer is made of PZT or PZT-containing material or lead-free piezoceramics. The thickness of the layer is preferably in the range <100 μm. The particle sizes in the layer are preferably in the range <1 μm, wherein the particle size is determined visually or by way of electron microscopy. Moreover, the layer preferably has a porous to dense structure, preferably >95% of the theoretical density.

The adhesion and sufficient bonding strength between the layer and the substrate or of the carrier preferably takes place by way of a microstructural plastic deformation of the surface of the substrate or of the carrier, so-called mechanical anchoring.

The applied substrate preferably covers the substrate or the carrier entirely or partially after the coating process. Furthermore, the substrate or the carrier can comprise an intermediate layer, on which full or partial deposition takes place.

In a preferred embodiment, electrodes are arranged beneath and/or on top of the layer across the full surface or partial surface, which allow the piezoelectric operation of the layer. For example, the electrodes can be arranged beneath and/or on top of the layer in an interdigital structure.

Moreover, the layer may be structured or polarized. Preferably, the layer is structured during the deposition or thereafter, or polarized during the deposition or thereafter.

### EXEMPLARY EMBODIMENT: PZT ON STAINLESS STEEL

### Aerosol Deposition:

An aerosol is generated from PZT powder and a carrier gas in an aerosol generator. The aerosol is sprayed onto the stainless-steel substrate to be coated in a deposition chamber, in which negative pressure is generated with the aid of a vacuum pump, using a (slot-shaped) nozzle. The aerosol is accelerated due to the pressure difference between the aerosol bottle and the deposition chamber and impinges on the stainless-steel substrate at high speeds. The PZT particles break during impact, adhere to the substrate, and form a layer there, as shown in FIG. 2. Due to the movability of the stainless-steel substrate, which in contrast to the fixedly positioned nozzle is located on a movable table, coating can take place in a planar (large-surface-area) manner.

### Annealing

Some of the PZT-coated samples are annealed in the furnace at 300° C. for approximately 2 h.

### Metallizing

The stainless-steel substrate can be used as an electrode for the polarization process. The counter electrode is generated by sputtering a metal layer onto the PZT layer. Care must only be taken that an insulating PZT edge is preserved between the stainless-steel substrate and the sputter layer. This may be ensured through the use of an appropriate mask.

### Polarizing

An approximately 30 μm-thick PZT layer is polarized by a trapezoidal voltage signal.

### Measurement Results

The d33 value was determined on the polarized layers by means of a Berlincourt meter. The minima and maxima of the d33 measurement values ascertained in different locations of the sample surface are listed in Table 1.

TABLE 1
d33 measurement values (day 1 after polarization);
RT: room temperature (no annealing).

| | | | Annealing | | |
|---|---|---|---|---|---|
| | | Layer thickness | temperature | d33 min | d33 max |
| No. | Material | [μm] | [° C.] | [pC/N] | [pC/N] |
| 6 | FeNi | 28 | 300 | 26 | 38 |
| 8 | FeNi | 26 | RT | 10 | 17 |
| 9 | FeNi | 24 | RT | 5 | 14 |
| 10 | FeNi | 23 | 300 | 61 | 78 |
| 14 | FeNi | 18 | 300 | 37 | 43 |

The piezoelectric data show that a usable piezoelectric effect is successfully achieved under the above-described deposition conditions, despite the low temperatures.

1. A layer having piezoelectric properties, wherein no temperature treatment >500° C. takes place during and after coating.

2. The layer having piezoelectric properties according to claim 1, wherein the piezoelectric properties of the layer are formed at room temperature or by annealing at temperatures up to a maximum of 350° C.

3. The layer having piezoelectric properties according to claim 2, wherein the coating is applied to a substrate or a carrier by way of an aerosol deposition method of the powdered raw materials.

4. The layer having piezoelectric properties according to claim 1, wherein the layer is made of PZT or PZT-containing material or lead-free piezoceramics.

5. The layer having piezoelectric properties according to claim 1, wherein the substrate or the carrier is made of ceramic, plastic, glass, metal, semiconductor or a composite of the aforementioned materials.

6. The layer having piezoelectric properties according to claim 5, wherein the substrate or the carrier has a lower hardness than the bulk material of the powdered raw materials used for the aerosol deposition.

7. The layer having piezoelectric properties according to claim 1, wherein the bonding strength between the layer and the substrate or carrier is achieved by a microstructural plastic deformation of the surface of the substrate or of the carrier (mechanical anchoring).

8. The layer having piezoelectric properties according to claim 1, wherein the layer has a thickness <100 μm.

9. The layer having piezoelectric properties according to claim 1, wherein the layer has a porous to dense structure.

10. The layer having piezoelectric properties according to claim 1, wherein the particle sizes in the layer are less than 1 μm.

11. The layer having piezoelectric properties according to claim 1, wherein the layer entirely or partially covers the substrate or the carrier after the coating process.

12. The layer having piezoelectric properties according to claim 1, wherein the carrier is provided with an intermediate layer, to which the layer is deposited.

13. The layer having piezoelectric properties according to claim 11, wherein electrodes are arranged beneath or on top of the layer across the full surface, partial surface or in an interdigital structure, which allow the operation.

14. The layer having piezoelectric properties according to claim 1, wherein the substrate or the carrier has an arbitrary shape, such as curvatures.

15. The layer having piezoelectric properties according to claim 1, wherein the layer is structured or polarized during deposition or thereafter.

16. A method for producing a layer having piezoelectric properties, wherein no temperature treatment >500° C. takes place during and after coating since this would result in the formation of the piezoelectric properties.

17. The method according to claim 16, wherein the piezoelectric properties of the layer are formed at room temperature or by annealing at temperatures up to a maximum of 350° C.

18. The method according to claim 16, wherein the piezoelectric properties of the layer are formed at room temperature or by annealing at temperatures up to a maximum of 350° C., and the coating is applied to a suitable substrate or a suitable carrier by way of an aerosol deposition method of the powdered raw materials.

19. The method according to claim 1, wherein the layer is made of PZT or PZT-containing material or lead-free piezoceramics.

20. The method according to claim 1, wherein the powder and/or the substrate or the carrier are not heated by means of an external heat source to high temperatures above 350° C. during coating.

21. The method according to claim 1, wherein the substrate or the carrier is made of ceramic, plastic, glass, metal, semiconductor or a composite of the aforementioned materials.

22. The method according to claim 21, wherein the substrate or the carrier has a lower hardness than the bulk material of the powdered raw materials used for the aerosol deposition.

23. The method according to claim 1, wherein the bonding strength between the layer and the substrate or carrier is achieved, among other things, by a microstructural plastic deformation of the surface of the substrate or of the carrier (mechanical anchoring).

24. The method according to claim 1, wherein the layer has a thickness <100 μm and a porous to dense structure, and the particle sizes in the layer are less than 1 μm.

25. The method according to claim 1, wherein the layer entirely or partially covers the substrate or the carrier after the coating process.

26. The method according to claim 1, wherein the carrier is provided with an intermediate layer, onto which full or partial deposition takes place.

27. The method according to claim 1, wherein electrodes are arranged beneath or on top of the layer across the full surface or partial surface, which allow the operation.

28. The method according to claim 27, wherein electrodes are arranged beneath or on top of the layer in an interdigital structure, which allow the operation.

29. The method according to claim 1, wherein the substrate or the carrier has an arbitrary shape, such as curvatures.

30. The method according to claim 1, wherein the layer is structured during deposition or thereafter.

31. The method according to claim 1, wherein the layer is polarized during deposition or thereafter.
